(19) United States
(12) Patent Application Publication
(10) Pub. No.: US 2025/0380459 A1
(43) Pub. Date: Dec. 11, 2025

(54) SEMICONDUCTOR DEVICE, METHOD OF MANUFACTURING SEMICONDUCTOR DEVICE, AND ELECTRONIC APPARATUS

(71) Applicant: INSTITUTE OF MICROELECTRONICS, CHINESE ACADEMY OF SCIENCES, Beijing (CN)

(72) Inventors: Qingzhu ZHANG, Beijing (CN); Renjie JIANG, Beijing (CN); Guanqiao SANG, Beijing (CN); Qingkun LI, Beijing (CN); Lei CAO, Beijing (CN); Peng WANG, Beijing (CN); Huaxiang YIN, Beijing (CN)

(21) Appl. No.: 19/016,033

(22) Filed: Jan. 10, 2025

(30) Foreign Application Priority Data
Jun. 11, 2024 (CN) 202410749434.5

(51) Int. Cl. H10D 30/67; H10D 30/01; H10D 64/01

(52) U.S. Cl. CPC H10D 30/6735; H10D 30/0312; H10D 30/6757; H10D 64/017

(57) ABSTRACT

The present disclosure provides a semiconductor device, a method and an electronic apparatus. The semiconductor device includes a substrate; a channel layer stacking portion including multiple channel layers, a length direction of the channel layer is perpendicular to the thickness direction of the substrate, and the channel layer includes a first end, a middle section and a second end in the length direction; a gate-all-around surrounding the middle section; a source/drain functional portion; and a first spacer between the source/drain functional portion and the gate-all-around, between the first ends of adjacent channel layers and between the second ends of the adjacent channel layers. The first spacer includes first and second portions in the length direction, the first portion is in contact with the gate-all-around, the second portion is in contact with the source/drain functional portion. A material of the first portion is different from that of the second portion.

### CROSS REFERENCE TO RELATED APPLICATION

This application claims priority to Chinese Patent Application No. 202410749434.5, filed on Jun. 11, 2024, the entire content of which is incorporated herein in its entirety by reference.

### TECHNICAL FIELD

The present disclosure relates to a field of semiconductor technology, in particular to a semiconductor device, a method of manufacturing a semiconductor device, and an electronic apparatus.

### BACKGROUND

As a continuous miniaturization of a feature size of an integrated circuit, nano Gate-All-Around Field Effect Transistor (GAA-FET) has become a next-generation key structure to achieve a size miniaturization. A channel of the GAA-FET is mainly a stacked nanosheet structure. A growth crystal orientation of the stacked nanosheet structure is different from growth crystal orientations of source/drain electrodes, which may easily lead to a source/drain dislocation, thereby affecting a performance of the semiconductor device.

### SUMMARY

In a first aspect of the present disclosure, a semiconductor device is provided, including:
a substrate;
a channel layer stacking portion formed on a side of the substrate, where the channel layer stacking portion includes a plurality of channel layers arranged in a thickness direction of the substrate, a length direction of the channel layer is perpendicular to the thickness direction of the substrate, and each of the plurality of channel layers includes a first end, a middle section and a second end arranged in the length direction of the channel layer;
a gate-all-around surrounding the middle section of the channel layer with respect to the length direction of the channel layer;
a source/drain functional portion including a source portion and a drain portion, where the source portion and the drain portion are located on two opposite sides of the channel layer stacking portion in the length direction of the channel layer; and
a first spacer located between the source/drain functional portion and the gate-all-around, between first ends of adjacent channel layers and between second ends of the adjacent channel layers, where the first spacer includes a first portion and a second portion arranged in the length direction of the channel layer, the first portion is in contact with the gate-all-around, the second portion is in contact with the source/drain functional portion, and a material of the first portion is different from a material of the second portion.

In a second aspect of the present disclosure, a method of manufacturing a semiconductor device is provided, including:
providing a substrate;
forming a stack epitaxy structure on a side of the substrate, and thinning a preset region in the stack epitaxy structure on two sides in a first direction, so as to form a thinned region and a reserved region, where the stack epitaxy structure includes a plurality of channel formation layers and a plurality of sacrificial layers alternately arranged in a direction away from the substrate;
forming a dummy gate covering two side surfaces of the thinned region in a second direction and covering a surface of the thinned region on a side of the thinned region away from the substrate, where a preset gap is formed between the dummy gate and the reserved region, and the second direction is perpendicular to each of the first direction and a thickness direction of the substrate;
removing a portion of the sacrificial layer corresponding to the preset gap to form a hollow portion;
forming a first portion of a first spacer in the hollow portion, where a material of the first portion is different from a material of the sacrificial layer;
patterning the reserved region such that a size of the reserved region in the second direction is a preset size, so as to pattern the sacrificial layer to form a second portion of the first spacer and pattern the channel formation layer to form a channel layer, and then form a channel layer stacking portion, where the channel layer stacking portion includes a plurality of channel layers arranged in the thickness direction of the substrate, a length direction of the channel layer is parallel to the second direction, and each of the plurality of channel layers includes a first end, a middle section and a second end arranged in the length direction of the channel layer;
removing the dummy gate to expose a portion of the sacrificial layer corresponding to the thinned region, and removing the portion of the sacrificial layer corresponding to the thinned region;
forming a gate-all-around surrounding the middle section with respect to the length direction of the channel layer, where the first portion is in contact with the gate-all-around; and
forming a source/drain functional portion, where the source/drain functional portion includes a source portion and a drain portion, the source portion and the drain portion are located on two opposite sides of the channel layer stacking portion in the length direction of the channel layer, and the source/drain functional portion is in contact with each of the second portion and the channel layer.

In a third aspect of the present disclosure, an electronic apparatus is provided, including at least one semiconductor device provided by the first aspect and/or at least one semiconductor device manufactured by the method provided by the second aspect.

### BRIEF DESCRIPTION OF THE DRAWINGS

Various other advantages and benefits will be clear to those ordinary skilled in the art by reading the following detailed descriptions of preferred embodiments. Accompanying drawings are only for the purpose of illustrating the preferred embodiments, and are not considered as limiting the present disclosure. Moreover, the same reference numerals are used to indicate the same components throughout the accompanying drawings, in which:

FIG. 1 shows a schematic diagram of a structure of a semiconductor device provided by the embodiments of the present disclosure;

FIG. 2 shows a cross-sectional view taken along M-M′ in FIG. 1;

FIG. 3 shows a flowchart of a method of manufacturing a semiconductor device provided by the embodiments of the present disclosure;

FIG. 4 shows a schematic diagram of a layer structure in a method of manufacturing a semiconductor device provided by the embodiments of the present disclosure;

FIG. 5 shows a schematic diagram of a structure of a semiconductor device provided by the embodiments of the present disclosure in a manufacturing process;

FIG. 6 shows a top view of FIG. 5;

FIG. 7 to FIG. 13 show schematic diagrams of layer changes in a method of manufacturing a semiconductor device provided by the embodiments of the present disclosure; and

FIG. 14 to FIG. 18 show schematic diagrams of layer changes in another method of manufacturing a semiconductor device provided by the embodiments of the present disclosure.

Reference numerals are as follows:
1: semiconductor device; y: length direction; 10: second spacer; 11: substrate; 12: channel layer stacking portion; 121: channel layer; 1211: first end; 1212: middle section; 1213: second end; 13: gate-all-around; 14: source/drain functional portion; 15: first spacer; 151: first portion; 152: second portion; 16: stack epitaxy structure; 161: channel formation layer; 162: sacrificial layer; A1: thinned region; A2: reserved region; 17: dummy gate; L: preset gap; 18: hollow portion; 19: second spacer material layer; 20: trench isolation layer.

### DETAILED DESCRIPTION OF EMBODIMENTS

Exemplary embodiments of the present disclosure will be described in more detail below with reference to the accompanying drawings. Although the exemplary embodiments of the present disclosure are shown in the accompanying drawings, it should be understood that the present disclosure may be implemented in various forms and should not be limited by the embodiments set forth herein. On the contrary, these embodiments are provided for a more thorough understanding of the present disclosure, and may fully convey the scope of the present disclosure to those ordinary skilled in the art.

It should be understood that terms used herein are for the purpose of describing specific example embodiments only and are not intended to be limiting them. Unless the context clearly indicates otherwise, the singular forms “a”, “an” and “the” as used herein may also include plural forms. Terms “include”, “comprise”, “contain” and “have” are inclusive and thus indicate the presence of the described features, steps, operations, elements and/or components, but do not exclude the presence or addition of one or more other features, steps, operations, elements, components, and/or combinations thereof. Method steps, procedures, and operations described herein are not to be interpreted as that they are necessarily required to be executed in the described or illustrated specific order, unless the execution order is explicitly indicated. It should also be understood that additional or alternative steps may be used.

Although terms “first”, “second”, “third”, etc. may be used herein to describe a plurality of elements, components, regions, layers and/or segments, these elements, components, regions, layers and/or segments should not be limited by the terms. The terms may only be used to distinguish an element, component, region, layer or segment from another element, component, region, layer or segment. Unless the context clearly indicates, the terms such as “first” and “second” and other numerical terms do not imply an order or a sequence when used herein. Therefore, a first element, a first component, a first region, a first layer or a first segment discussed below may be called a second element, a second component, a second region, a second layer or a second segment without departing from teachings of the exemplary embodiments.

For the convenience of description, spatial relative relationship terms may be used herein to describe a relationship between an element or feature and another element or feature as shown in the drawings. The relative relationship terms are, for example, “interior”, “exterior”, “inside”, “outside”, “below”, “under”, “above”, “on”, etc. The spatial relative relationship terms are intended to include different orientations of an apparatus in use or operation in addition to those depicted in the drawings. For example, if the apparatus in the drawings is reversed, an element described as “below another element or feature” or “under another element or feature” may be subsequently oriented as “above another element or feature” or “on another element or feature”. Therefore, the exemplary term “under . . . ” may include both orientations above and below. The apparatus may be otherwise oriented (rotated by 90 degrees or in other directions) and the spatial relative descriptors used herein are interpreted accordingly.

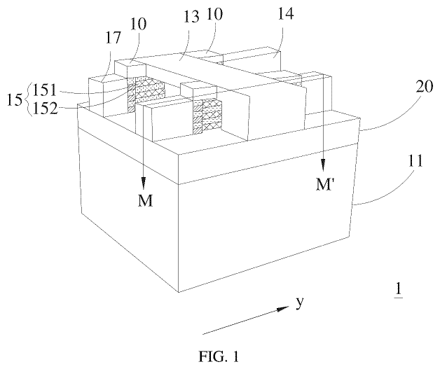

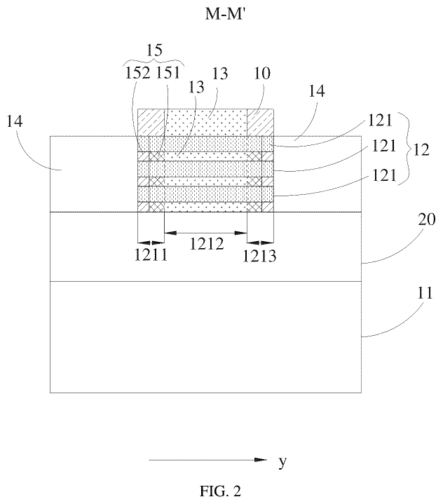

As shown in FIG. 1 and FIG. 2, according to the embodiments of the present disclosure, a semiconductor device 1 is provided, including a substrate 11, a channel layer stacking portion 12, a gate-all-around 13, a source/drain functional portion 14 and a first spacer 15. The channel layer stacking portion 12 is formed on a side of the substrate 11 and includes a plurality of channel layers 121 arranged in a thickness direction of the substrate 11. A length direction y of the channel layer 121 is perpendicular to the thickness direction of the substrate 11. The channel layer 121 includes a first end 1211, a middle section 1212 and a second end 1213 arranged in the length direction y. The gate-all-around 13 surrounds the middle section 1212 with respect to the length direction y of the channel layer 121. The source/drain functional portion 14 includes a source portion and a drain portion, and the source portion and the drain portion are located on two opposite sides of the channel layer stacking portion 12 in the length direction y. The first spacer 15 is located between the source/drain functional portion 14 and the gate-all-around 13, between the first ends 1211 of adjacent channel layers 121 and between the second ends 1213 of the adjacent channel layers 121. The first spacer 15 includes a first portion 151 and a second portion 152 arranged in the length direction y. The first portion 151 is in contact with the gate-all-around 13, the second portion 152 is in contact with the source/drain functional portion 14, and a material of the first portion 151 is different from a material of the second portion 152.

The semiconductor device 1 provided in the present disclosure includes the substrate 11, the channel layer stacking portion 12, the gate-all-around 13, the source/drain functional portion 14 and the first spacer 15. The channel layer stacking portion 12 is formed on a side of the substrate 11 and includes the plurality of channel layers 121 arranged in the thickness direction of the substrate 11. The length direction y of the channel layer 121 is perpendicular to the thickness direction of the substrate 11. The channel layer 121 includes the first end 1211, the middle section 1212 and the second end 1213 which are arranged in the length direction y. The gate-all-around 13 surrounds the middle section 1212 with respect to the length direction y of the channel layer 121, so that the gate-all-around 13 may be in fully contact with a circumferential surface of the channel layer 121 with respect to the length direction y of the channel layer 121, so as to suppress a current and improve the performance of the semiconductor device 1. The source/drain functional portion 14 includes the source portion and the drain portion, and the source portion and the drain portion are located at the two opposite sides of the channel layer stacking portion 12 in the length direction y. The first spacer 15 is located between the source/drain functional portion 14 and the gate-all-around 13, and is used to achieve an isolation of a source electrode from the gate-all-around 13 and an isolation of a drain electrode from the gate-all-around 13, and reduce the parasitic capacitance. Specifically, the first spacer 15 is located between the first ends 1211 of adjacent channel layers 121 and between the second ends 1213 of adjacent channel layers 121. That is, a first spacer 15 is formed between the first ends 1211 of two adjacent channel layers 121 in the thickness direction of the substrate 11, and a first spacer 15 is formed between the second ends 1213 of the two adjacent channel layers 121 in the thickness direction of the substrate 11. The first spacer 15 includes the first portion 151 and the second portion 152 arranged in the length direction y. The first portion 151 is in contact with the gate-all-around 13, the second portion 152 is in contact with the source/drain functional portion 14, and the material of the first portion 151 is different from the material of the second portion 152. Specifically, the first portion 151 is located on a side of the first spacer 15 close to the gate-all-around 13 and is in contact with the gate-all-around 13, the second portion 152 is located on a side of the first spacer 15 close to the source electrode or drain electrode and is in contact with the source electrode or drain electrode, and the material of the first portion 151 is different from the material of the second portion 152. Therefore, in the manufacturing process, the second portion 152 may be made of a material with a small dislocation from the source/drain functional portion 14 to reduce a dislocation phenomenon between the source/drain functional portion 14 and the channel layer stacking portion 12, so as to reduce a source/drain defect and maintain a stress, thereby greatly improving a performance of the semiconductor device 1, and not introducing the source/drain defect while applying the stress to a channel. Moreover, in the manufacturing process, an influence of the manufacturing process on the second portion 152 may be isolated by the first portion 151, so as to keep the second portion 152 in contact with the source/drain functional portion 14.

Specifically, in the manufacturing process, the channel layer stacking portion 12 is formed by patterning channel formation layers 161 and sacrificial layers 162 which are stacked alternately in a direction away from the substrate 11. The channel formation layer 161 is used to form the channel layer 121. A portion of the sacrificial layer 162 located between adjacent middle sections 1212 is removed to form a portion of the gate-all-around in contact with the middle section 1212. A portion of the sacrificial layer 162 in contact with the first end 1211 and the second end 1213 is reserved as the second portion 152 to be in contact with the source/drain functional portion 14, thereby reducing a dislocation problem. At the same time, a damage caused by an implantation of the source/drain functional portion 14 may be blocked, a contact resistance of the source/drain functional portion 14 may be reduced and an on-state current and a switching ratio may be improved, so as to improve a driving ability of the semiconductor device 1 and achieve the high-performance semiconductor device 1. The first portion 151 may be formed before the formation of the second portion 152. When the portion of the sacrificial layer 162 between the adjacent middle sections 1212 is removed, the second portion 152 may be protected by the first portion 151, so as to prevent over-etching of the second portion 152 due to a contact of an etchant with the second portion 152. Specifically, the substrate 11 may be any substrate known to those skilled in the art for supporting the semiconductor device 1, such as a silicon-on-insulator (SOI) substrate, a bulk silicon substrate, a silicon carbide substrate, a germanium substrate, a silicon germanium substrate, a gallium arsenide substrate or a germanium-on-insulator substrate. The substrate 11 may also be a stack structure formed of a plurality of semiconductor material layers.

Specifically, the material of the first portion 151 may include silicon nitride. The material of the second portion 152 may include germanium silicon. The material of the source/drain functional portion 14 may include silicon carbide or germanium silicon. The source/drain functional portion 14 and the second portion 152 have similar growth crystal orientations, so that the dislocation problem may be improved.

In a feasible embodiment, as shown in FIG. 1 and FIG. 2, the semiconductor device 1 further includes a second spacer 10. The second spacer 10 is located on a side of the channel layer stacking portion 12 away from the substrate 11 and on two sides of the gate-all-around 13 in the length direction y. An orthographic projection of the second spacer 10 on the substrate 11 covers an orthographic projection of the first spacer 15 on the substrate 11.

In the above-mentioned embodiment, the second spacer 10 may isolate the source/drain functional portion 14 from the gate-all-around 13, so as to prevent the source/drain functional portion 14 from being in contact with the gate-all-around 13.

Specifically, in the length direction y of the channel layer 121, a size of an overlapping portion in the orthographic projections of the second spacer 10 and the second portion 152 on the substrate 11 is in a range of 3 nm to 10 nm.

In the manufacturing process, the channel layer stacking portion 12 is formed by patterning the channel formation layers 161 and the sacrificial layers 162 which are alternately stacked in the direction away from the substrate 11. The channel formation layers 161 and the sacrificial layers 162 need to be patterned. In the manufacturing process, the second spacer 10 may be formed first and then reused as a mask for patterning the channel formation layers 161 and the sacrificial layers 162. A size of the second spacer 10 is defined, so as to control a size of the second portion 152 formed after patterning the sacrificial layer 162.

In a feasible embodiment, a material of the second spacer 10 is the same as the material of the first portion 151.

In the above-mentioned embodiment, the second spacer 10 and the first portion 151 may be made of the same material and may be manufactured by the same process, thereby reducing the number of process steps, simplifying a manufacturing process and saving a manufacturing cost.

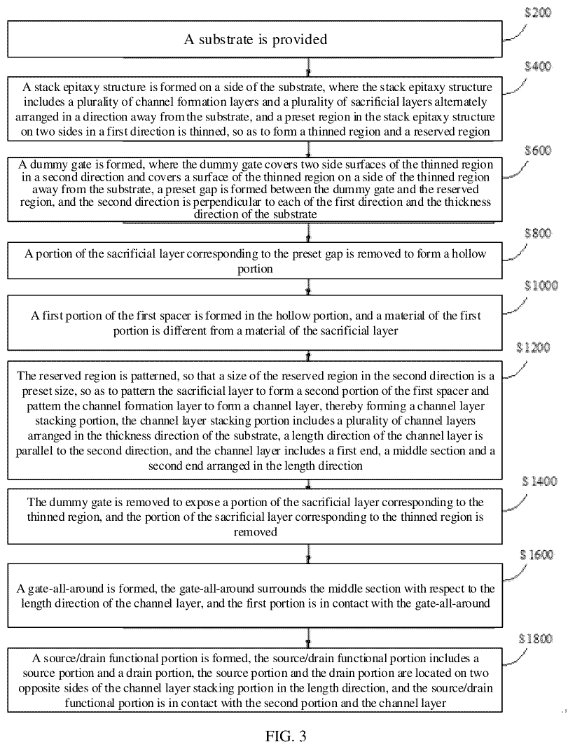

The present disclosure further provides a method of manufacturing the semiconductor device 1. As shown in FIG. 3, the method includes steps S200 to S1800.

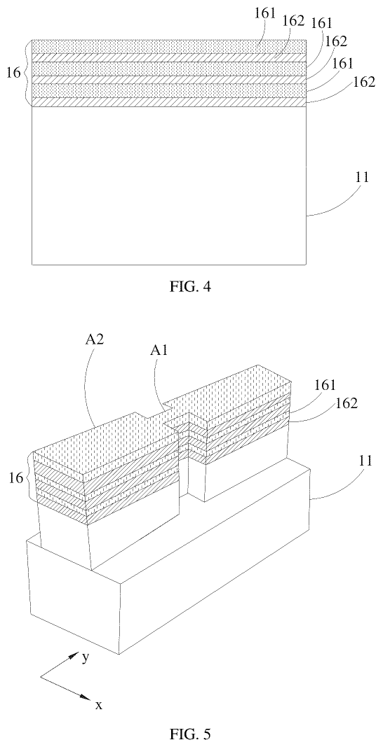

In S200, as shown in FIG. 4, a substrate 11 is provided.

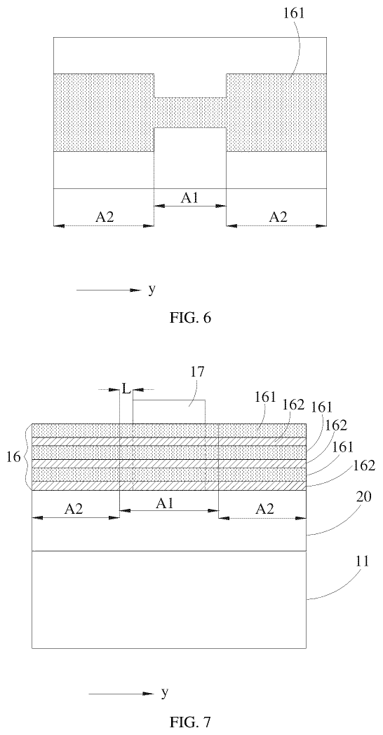

In S400, as shown in FIG. 4, a stack epitaxy structure 16 is formed on a side of the substrate 11, where the stack epitaxy structure 16 includes a plurality of channel formation layers 161 and a plurality of sacrificial layers 162 alternately arranged in a direction away from the substrate 11; and as shown in FIG. 5 and FIG. 6, a preset region in the stack epitaxy structure 16 on two sides in a first direction x is thinned, so as to form a thinned region A1 and a reserved region A2.

Specifically, a material of the channel formation layer 161 may include silicon, and a material of the sacrificial layer 162 may include germanium silicon. The preset region is used to form the gate-all-around 13 and the second portion 152. The material of the sacrificial layer 162 and the material of the source/drain functional portion 14 have the same or similar lattice, so that the dislocation problem may be improved after the contact. The stack epitaxy structure 16 is used to form the channel layer stacking portion 12 and the second portion 152 of the first spacer 15.

In S600, as shown in FIG. 7, a dummy gate 17 is formed, where the dummy gate 17 covers two side surfaces of the thinned region A1 in a second direction y and covers a surface of the thinned region A1 on a side of the thinned region A1 away from the substrate 11, a preset gap L is formed between the dummy gate 17 and the reserved region A2, and the second direction y is perpendicular to each of the first direction x and the thickness direction of the substrate 11.

Specifically, the dummy gate 17 is formed in the thinned region A1, and the preset gap L is formed between the dummy gate 17 and each of the reserved regions A2 on both sides. The preset gap L is used to form the first portion 151 of the first spacer 15.

Specifically, a size of the preset gap L in the second direction y may be in a range of 3 nm to 20 nm.

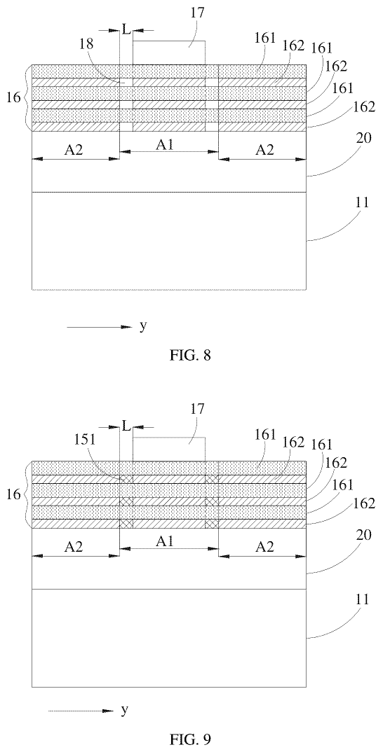

In S800, as shown in FIG. 8, a portion of the sacrificial layer 162 corresponding to the preset gap L is removed to form a hollow portion 18.

Specifically, a dry etching method or a wet etching method may be used to remove the portion of the sacrificial layer 162 corresponding to the preset gap L. Such manufacturing method is simple and has a high yield. Compared with the manufacturing method in the related art in which the sacrificial layer 162 would be etched in the second direction y and filling of other isolation medium would be performed, etching is performed in the first direction x in the above embodiment, which may achieve a high etching yield and be less likely to cause over-etching or under-etching, so that an impact on sizes of the dummy gate 17 and the isolation medium may be reduced.

In S1000, as shown in FIG. 9, a first portion 151 of a first spacer 15 is formed in the hollow portion 18, where a material of the first portion 151 is different from a material of the sacrificial layer 162.

Specifically, the material of the first portion 151 may be selected from a material that is not easily affected by an etching solution for etching the sacrificial layer 162, so that the first portion 151 is not easily affected by the etching solution in a subsequent removal of a portion of the sacrificial layer 162 blocked by the dummy gate 17, thereby preventing an over-etching problem.

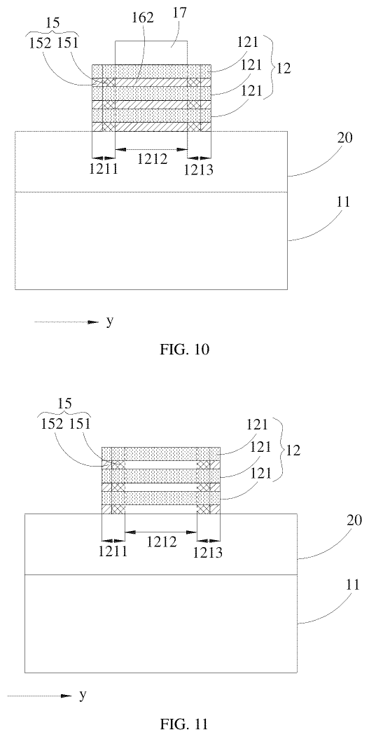

In S1200, as shown in FIG. 10, the reserved region A2 is patterned such that a size of the reserved region A2 in the second direction y is a preset size, so as to pattern the sacrificial layer 162 to form a second portion 152 of the first spacer 15 and pattern the channel formation layer 161 to form a channel layer 121, thereby forming the channel layer stacking portion 12 including a plurality of channel layers 121 arranged in the thickness direction of the substrate 11. The length direction y of the channel layer 121 is parallel to the second direction y, and the channel layer 121 includes the first end 1211, the middle section 1212 and the second end 1213 arranged in the length direction.

Specifically, the reserved region A2 is patterned by an etching process to remove a portion of the reserved region A2 at an end of the reserved region A2 away from the thinned region A1, so as to reduce the size of the reserved region A2 in the second direction y. The size of the reserved region A2 in the second direction y is a preset size, so that a portion of the sacrificial layer 162 located in the reserved region A2 may be reserved and used as the second portion 152 of the first spacer 15 for being in contact with the source/drain functional portion 14. Since the material of the sacrificial layer 162 and the material of the source/drain functional portion 14 have the same or similar lattice, the second portion 152 may be reserved to be in contact with the source/drain functional portion 14, so as to improve the dislocation problem.

Specifically, the reserved region A2 is patterned using an etching process such that the channel formation layer 161 is patterned to form the channel layer 121. The length direction y of the channel layer 121 is perpendicular to the thickness direction of the substrate 11. The channel layer 121 includes the first end 1211, the middle section 1212 and the second end 1213 arranged in the length direction y. The second portion 152 is formed between first ends 1211 of adjacent channel layers 121 in the thickness direction of the substrate 11 and between second ends 1213 of the adjacent channel layers 121 in the thickness direction of the substrate 11. The sacrificial layer 162 not removed is still reserved between middle sections 1212 of the adjacent channel layers 121 in the thickness direction of the substrate 11.

In S1400, as shown in FIG. 11, the dummy gate 17 is removed to expose a portion of the sacrificial layer 162 corresponding to the thinned region A1, and the portion of the sacrificial layer 162 corresponding to the thinned region A1 is removed.

Specifically, after the dummy gate 17 is removed, a portion of the sacrificial layer 162, which is between the middle sections 1212 of the adjacent channel layers 121 in the thickness direction of the substrate 11, is exposed. Such portion of the sacrificial layer 162 may be removed by dry etching or wet etching to leave a space for the arrangement of the gate-all-around 13, so that the gate-all-around 13 may surround the middle section 1212 with respect to the length direction y of the channel layer 121.

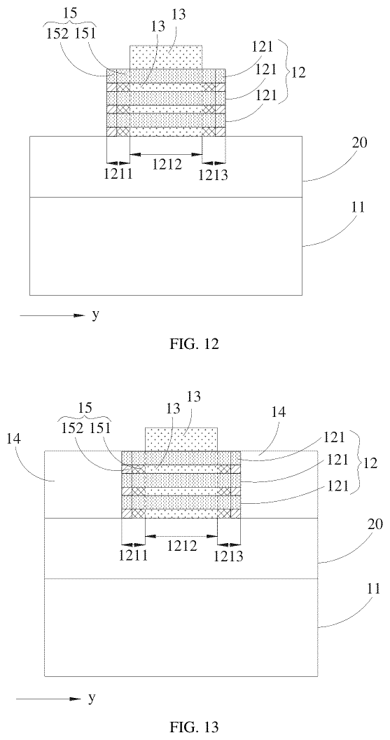

In S1600, as shown in FIG. 12, a gate-all-around 13 is formed, where the gate-all-around 13 surrounds the middle section 1212 with respect to the length direction of the channel layer 121, and the first portion 151 is in contact with the gate-all-around 13.

In S1800, as shown in FIG. 13, a source/drain functional portion 14 is formed, where the source/drain functional portion 14 includes a source portion and a drain portion, the source portion and the drain portion are located on two opposite sides of the channel layer stacking portion 12 in the length direction y, and the source/drain functional portion 14 is in contact with each of the second portion 152 and the channel layer 121.

In the above-mentioned embodiment, the material of the source/drain functional portion 14 and the material of the second portion 152 have the same or similar lattice, so that the dislocation problem may be improved after the contact.

In the above-mentioned manufacturing method provided by the present disclosure, on the one hand, the first spacer 15 including the first portion 151 and the second portion 152 is provided, and the second portion 152 may be made of a material with a lattice that is the same as or similar to that of the source/drain functional portion 14, so that the dislocation problem may be improved after the contact. In addition, the first portion 151 may be used for etching blocking to prevent an impact on a yield of the second portion 152 in the process of etching the sacrificial layer 162 in the thinned region A1, thereby ensuring an isolation function of the first spacer 15. On the other hand, in the above-mentioned manufacturing method, the manufacturing method of the first spacer 15 is simple and has a high yield, an etching process in the process of forming the first portion 151 is simple, and the first portion 151 may provide a blocking function for the second portion 152, which may improve a manufacturing yield of the second portion 152. At the same time, the manufacturing process for the second portion 152 is simple.

Before forming the dummy gate 17, the above-mentioned manufacturing method further includes forming a trench and a trench isolation layer 20, for isolating adjacent transistor devices. The trench is formed between adjacent channel layer stacking portions 12, and the trench isolation layer 20 is formed in the trench.

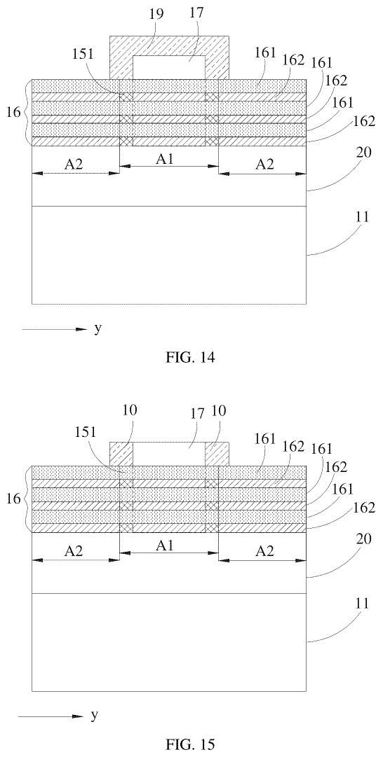

In a feasible embodiment, the manufacturing method further includes:
as shown in FIG. 14, forming a second spacer material layer 19, where the second spacer material layer 19 covers a surface of the dummy gate 17 on a side of the dummy gate 17 away from the substrate 11 and covers two opposite surfaces of the dummy gate 17 in the second direction y, the second spacer material layer 19 is in contact with the stack epitaxy structure 16, and an orthographic projection of the second spacer material layer 19 on the substrate 11 covers an orthographic projection of the first spacer 15 on the substrate 11; and
as shown in FIG. 15, removing a portion of the second spacer material layer 19 on the side of the dummy gate 17 away from the substrate 11, so as to form the second spacer 10.

The above-mentioned steps may be performed before the step S1200 (i.e. patterning the reserved region A2).

In the above-mentioned embodiment, the second spacer material layer 19 may be formed first and then patterned to form the second spacer 10. A further isolation of the gate-all-around 13 from the source/drain functional portion 14 may be achieved through the second spacer 10.

In a feasible embodiment, the material of the second spacer material layer 19 is the same as the material of the first portion 151.

In the above-mentioned embodiment, the second spacer material layer 19 and the first portion 151 may be manufactured by the same manufacturing process, thereby simplifying a manufacturing process and saving a manufacturing cost.

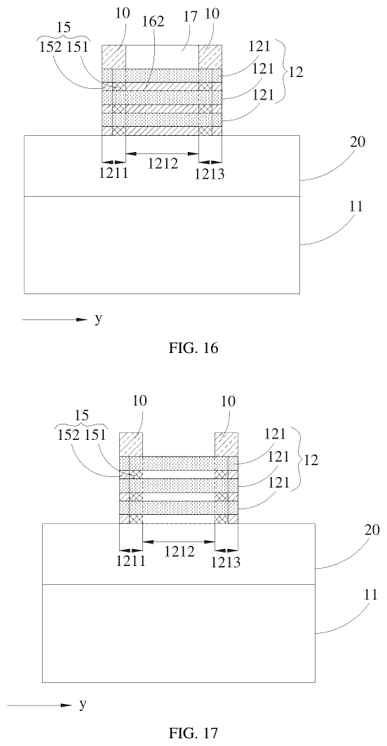

In a feasible embodiment, as shown in FIG. 16, the reserved region A2 is patterned after forming the second spacer material layer 19. An orthographic projection of the reserved region A2 on the substrate 11 includes: a first part overlapping with the orthographic projection of the second spacer material layer 19 on the substrate 11 and a second part not overlapping with the orthographic projection of the second spacer material layer 19 on the substrate 11. The patterning the reserved region A2 includes removing a portion of the reserved region A2 corresponding to the second part.

In the above-mentioned embodiment, the second spacer material layer 19 may further provide an etching blocking function for the patterning of the reserved region A2, so as to control an etching range of the reserved region A2.

In a feasible embodiment, as shown in FIG. 17, the portion of the second spacer material layer 19 on the side of the dummy gate 17 away from the substrate 11 is removed while removing the dummy gate 17.

In the above-mentioned embodiment, in the process of removing the dummy gate 17, the second spacer material layer 19 may be patterned to remove the portion of the second spacer material layer 19 on the side of the dummy gate 17 away from the substrate 11, so as to form the second spacer 10. Subsequently, after the gate-all-around 13 is formed at the position of the original dummy gate 17, the gate-all-around 13 may be in contact with the second spacer 10, and a further isolation of the gate-all-around 13 from the source/drain functional portion 14 may be achieved through the second spacer 10.

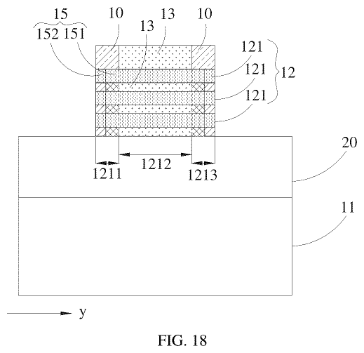

In the above-mentioned embodiment, as shown in FIG. 18, after removing the dummy gate 17, the gate-all-around 13 is formed. The gate-all-around 13 surrounds the middle section 1212 with respect to the length direction of the channel layer 121, and the first portion 151 is in contact with the gate-all-around 13. As shown in FIG. 2, the source/drain functional portion 14 is formed. The source/drain functional portion 14 includes a source portion and a drain portion, and the source portion and the drain portion are located at the two opposite sides of the channel layer stacking portion 12 in the length direction y. The source/drain functional portion 14 is in contact with the second portion 152 and the channel layer 121.

The present disclosure further provides an electronic apparatus. The electronic apparatus includes at least one semiconductor device 1 provided in the above-mentioned embodiments, and/or at least one semiconductor device 1 manufactured by any one of the manufacturing methods provided in the above-mentioned embodiments.

In the semiconductor device 1 of the electronic apparatus, the first spacer 15 includes the first portion 151 and the second portion 152 arranged in the length direction y. The first portion 151 is in contact with the gate-all-around 13, the second portion 152 is in contact with the source/drain functional portion 14, and the material of the first portion 151 is different from the material of the second portion 152. Specifically, the first portion 151 is located on a side of the first spacer 15 close to the gate-all-around 13 and is in contact with the gate-all-around 13, the second portion 152 is located on a side of the first spacer 15 close to the source electrode or drain electrode and is in contact with the source electrode or drain electrode, and the material of the first portion 151 is different from the material of the second portion 152. Therefore, in the manufacturing process, the second portion 152 may be made of a material with a small dislocation from the source/drain functional portion 14 to reduce a dislocation phenomenon between the source/drain functional portion 14 and the channel layer stacking portion 12, so as to reduce a source/drain defect and maintain a stress, thereby greatly improving a performance of the semiconductor device 1, and not introducing the source/drain defect while applying the stress to a channel. Therefore, a contact resistance of the source/drain functional portion 14 may be reduced, and an on-state current and a switching ratio may be improved, so as to improve a driving ability of the semiconductor device 1 and achieve the high-performance semiconductor device 1. Moreover, in the manufacturing process, an influence of the manufacturing process on the second portion 152 may be isolated by the first portion 151, so as to keep the second portion 152 in contact with the source/drain functional portion 14. By providing the first spacer 15 including the first portion 151 and the second portion 152, the forming process of the first portion 151 has a high yield, and the first portion 151 may be used as a barrier for subsequent etching, so as to ensure a yield of the second portion 152, so that the manufacturing process of the electronic apparatus is simple and has a high yield. The electronic apparatus provided by the present disclosure may include a secure digital card, a solid state drive, a computing-in-memory chip or brain-like chip, which will not be particularly limited in the present disclosure.

The above are only the preferred embodiments of the present disclosure. However, the scope of protection of the present disclosure is not limited thereto. Any changes or substitutions that may be easily thought of by those skilled in the art within the technical scope disclosed in the present disclosure should be included in the scope of protection of the present disclosure. Therefore, the scope of protection of the present disclosure should be based on the scope of protection of the claims.

What is claimed is:

1. A semiconductor device, comprising:
a substrate;
a channel layer stacking portion formed on a side of the substrate, wherein the channel layer stacking portion comprises a plurality of channel layers arranged in a thickness direction of the substrate, a length direction of the channel layer is perpendicular to the thickness direction of the substrate, and each of the plurality of channel layers comprises a first end, a middle section and a second end arranged in the length direction of the channel layer;
a gate-all-around surrounding the middle section of the channel layer with respect to the length direction of the channel layer;
a source/drain functional portion comprising a source portion and a drain portion, wherein the source portion and the drain portion are located on two opposite sides of the channel layer stacking portion in the length direction of the channel layer; and
a first spacer located between the source/drain functional portion and the gate-all-around, between first ends of adjacent channel layers and between second ends of the adjacent channel layers, wherein the first spacer comprises a first portion and a second portion arranged in the length direction of the channel layer, the first portion is in contact with the gate-all-around, the second portion is in contact with the source/drain functional portion, and a material of the first portion is different from a material of the second portion.

2. The semiconductor device according to claim 1, further comprising:
a second spacer, wherein the second spacer is located on a side of the channel layer stacking portion away from the substrate and on two sides of the gate-all-around in the length direction of the channel layer, and an orthographic projection of the second spacer on the substrate covers an orthographic projection of the first spacer on the substrate.

3. The semiconductor device according to claim 1, wherein the material of the first portion comprises silicon nitride, and the material of the second portion comprises silicon carbide or germanium silicon.

4. The semiconductor device according to claim 2, wherein a material of the second spacer is same as the material of the first portion.

5. A method of manufacturing a semiconductor device, comprising:
providing a substrate;
forming a stack epitaxy structure on a side of the substrate, and thinning a preset region in the stack epitaxy structure on two sides in a first direction, so as to form a thinned region and a reserved region, wherein the stack epitaxy structure comprises a plurality of channel formation layers and a plurality of sacrificial layers alternately arranged in a direction away from the substrate;
forming a dummy gate covering two side surfaces of the thinned region in a second direction and covering a surface of the thinned region on a side of the thinned region away from the substrate, wherein a preset gap is formed between the dummy gate and the reserved region, and the second direction is perpendicular to each of the first direction and a thickness direction of the substrate;
removing a portion of the sacrificial layer corresponding to the preset gap to form a hollow portion;
forming a first portion of a first spacer in the hollow portion, wherein a material of the first portion is different from a material of the sacrificial layer;
patterning the reserved region such that a size of the reserved region in the second direction is a preset size, so as to pattern the sacrificial layer to form a second portion of the first spacer and pattern the channel formation layer to form a channel layer, and then form a channel layer stacking portion, wherein the channel layer stacking portion comprises a plurality of channel layers arranged in the thickness direction of the substrate, a length direction of the channel layer is parallel to the second direction, and each of the plurality of channel layers comprises a first end, a middle section and a second end arranged in the length direction of the channel layer;
removing the dummy gate to expose a portion of the sacrificial layer corresponding to the thinned region, and removing the portion of the sacrificial layer corresponding to the thinned region;
forming a gate-all-around surrounding the middle section with respect to the length direction of the channel layer, wherein the first portion is in contact with the gate-all-around; and
forming a source/drain functional portion, wherein the source/drain functional portion comprises a source portion and a drain portion, the source portion and the drain portion are located on two opposite sides of the channel layer stacking portion in the length direction of the channel layer, and the source/drain functional portion is in contact with each of the second portion and the channel layer.

6. The method according to claim 5, further comprising:
forming a second spacer material layer, wherein the second spacer material layer covers a surface of the dummy gate on a side of the dummy gate away from the substrate and covers two opposite surfaces of the dummy gate in the first direction, the second spacer material layer is in contact with the stack epitaxy structure, and an orthographic projection of the second spacer material layer on the substrate covers an orthographic projection of the first spacer on the substrate; and
removing a portion of the second spacer material layer on the side of the dummy gate away from the substrate, so as to form a second spacer.

7. The method according to claim 6, wherein a material of the second spacer material layer is same as the material of the first portion.

8. The method according to claim 6, wherein the reserved region is patterned after forming the second spacer material layer, an orthographic projection of the reserved region on the substrate comprises a first part overlapping with the orthographic projection of the second spacer material layer on the substrate and a second part not overlapping with the orthographic projection of the second spacer material layer on the substrate, and the patterning the reserved region comprises removing a portion of the reserved region corresponding to the second part.

9. The method according to claim 6, wherein the portion of the second spacer material layer on the side of the dummy gate away from the substrate is removed while removing the dummy gate.

10. An electronic apparatus, comprising: at least one semiconductor device according to claim 1.

11. An electronic apparatus, comprising: at least one semiconductor device manufactured by using the method according to claim 5.
